(19) United States
(12) Patent Application Publication
(10) Pub. No.: US 2015/0054113 A1
(43) Pub. Date: Feb. 26, 2015

(54) SOLID-STATE IMAGE SENSING DEVICE AND PRODUCTION METHOD FOR SAME

(71) Applicant: Panasonic Intellectual Property Management Co., Ltd., Osaka (JP)

(72) Inventor: Jun SUZUKI, Kyoto (JP)

(21) Appl. No.: 14/529,052

(22) Filed: Oct. 30, 2014

Related U.S. Application Data
(63) Continuation of application No. PCT/JP2013/002700, filed on Apr. 22, 2013.

(30) Foreign Application Priority Data
Jun. 27, 2012 (JP) 2012-143970

(51) Int. Cl. H01L 27/146

(52) U.S. Cl. CPC H01L 27/14636
USPC 257/459; 438/98

(57) ABSTRACT

A solid-state image sensing device includes a substrate provided with an impurity region, an insulating film formed on the substrate, and a contact electrode penetrating the insulating film to be connected to the impurity region. The contact electrode is made of polysilicon containing boron, and has a lower electrode part buried in the insulating film and an upper electrode part protruding from a top surface of the insulating film. The polysilicon constituting the contact electrode has a maximum grain size of 2 nm or more and 30 nm or less. Silicide is formed in at least a surface portion of the upper electrode part.

### CROSS-REFERENCE TO RELATED APPLICATIONS

This is a continuation of International Application No. PCT/JP2013/002700 filed on Apr. 22, 2013, which claims priority to Japanese Patent Application No. 2012-143970 filed on Jun. 27, 2012. The entire disclosures of these applications are incorporated by reference herein.

### BACKGROUND

The present disclosure relates to a solid-state image sensing device including a contact region, and a method for producing the same.

Solid-state image sensing devices mounted on digital still cameras, e.g., CMOS sensors and CCD sensors, include an image sensing region having a plurality of photodiodes arranged in a two-dimensional array.

A size of pixels has been decreasing as the number of pixels increases and design rules become finer, and an area of the photodiodes is decreasing. The decrease in area of the photodiodes may lead to reduction of sensor properties. For example, saturation signal per pixel may be reduced, or sensitivity may be reduced due to reduction in aperture ratio and efficiency of light collection.

The solid-state image sensing device includes a photoelectric conversion part formed on a semiconductor substrate, such as a photodiode, etc., a charge transfer part having a charge transfer electrode for transferring a signal charge generated by the photoelectric conversion part, and a signal output part for converting the signal charge transferred by the charge transfer part to a voltage signal and outputting the voltage signal.

The signal output part may be a floating diffusion amplifier, for example. The floating diffusion amplifier is formed on a silicon substrate provided with an isolation region, etc., and includes an amplifier gate electrode made of a first electrode material, and a contact electrode made of a second electrode material and is in contact with a floating diffusion.

The first electrode material and the second electrode material may be polysilicon or amorphous silicon doped with N-type impurities such as phosphorus, etc. in a high concentration. In the solid-state image sensing device of this type, the impurities in the contact electrode may be diffused to the silicon substrate by heat applied in a process after the contact electrode is formed, and may affect the floating diffusion.

Japanese Unexamined Patent Publication No. 2009-170803 describes a technique for reducing the influence of the impurity diffusion on the floating diffusion. In a solid-state image sensing device described in Japanese Unexamined Patent Publication No. 2009-170803, a gate insulating film, a first electrode material film doped with N-type impurities such as phosphorus, arsenic, etc. in a high concentration, and a second electrode material film doped with the N-type impurities such as phosphorus, arsenic, etc. in a low concentration are stacked on a semiconductor substrate provided with a floating diffusion. An opening is formed in the gate insulating film to be located above the floating diffusion, and the second electrode material film is in contact with the floating diffusion in the opening. In the solid-state image sensing device, the concentration of the impurities contained in the second electrode material film is reduced to reduce the influence of the impurities in the second electrode material film on the floating diffusion, and to reduce expansion of an impurity diffusion layer constituting the floating diffusion.

When a saturation charge and the sensitivity decrease as the number of pixels increases and the design rules become finer, noise reduction increases in importance. Possible causes of the noise include crystal defects metallic contamination, etc. in a diffusion region in a pixel region such as the photodiodes, the floating diffusion, etc. In particular, when silicide is formed in a gate electrode or source/drain regions in the pixel region, metal used to form the silicide may be diffused to the diffusion region such as the photodiodes and the floating diffusion to generate noise, e.g., a white spot. To avoid this problem, the silicide is not formed in the pixel region in common solid-state image sensing devices (see, e.g., Japanese Unexamined Patent Publication No. 2006-245540).

A solid-state image sensing device in which an organic photoelectric conversion layer is stacked above a substrate for improved efficiency of light utilization has also been developed (see, e.g., Japanese Unexamined Patent Publication No. 2009-130090 etc.).

### SUMMARY

In the above-described solid-state image sensing devices, polysilicon doped with the N-type impurities such as phosphorus, arsenic, etc. is used. Since the polysilicon doped with the N-type impurities has a higher resistance than metal, the solid-state image sensing devices cannot sufficiently increase a rate of charge transfer. In the solid-state image sensing device of Japanese Unexamined Patent Publication No. 2009-170803, the amount of the impurities doped in the polysilicon is reduced to reduce the diffusion of the impurities to the floating diffusion formed in a surface of the substrate. Thus, the increase in rate of charge transfer cannot be expected. For reducing the resistance, the polysilicon can be silicided. However, the polysilicon doped with the N-type impurities such as phosphorus, arsenic, etc. has a large grain size. Therefore, when the polysilicon is silicided, a silicide formation reaction occurs along a grain boundary, the silicide reaches the surface of the substrate, and the diffusion region in the surface of the substrate is contaminated by metal. In particular, the diffusion region such as a charge storage part etc. contaminated by metal may generate the noise.

When metal with a low resistance is used as a material of the electrode, the rate of charge transfer can be increased, but an alloying reaction occurs at an interface between the diffusion region in the pixel region and the metal electrode, and the crystal defects may easily occur. Thus, use of the metal as the electrode material is not preferable because the noise is generated like in the case where the silicided polysilicon is used as the electrode material.

In the organic solid-state image sensing device, noise caused by the crystal defects at an interface between the charge storage part and the metal electrode particularly has adverse effects. In the organic solid-state image sensing device, a photoelectric conversion layer for generating a signal and the charge storage part are electrically connected, and the noise generated at the charge storage part is stored together with the signal charge, thereby greatly affecting the sensor properties.

In view of the foregoing, the present disclosure provides a solid-state image sensing device with reduced noise, and a method for producing the same.

A solid-state image sensing device according to an embodiment of the present disclosure is configured as described below.

Specifically, the solid-state image sensing device according to the embodiment of the present disclosure includes: a substrate provided with an impurity region; an insulating film formed on the substrate; and a contact electrode penetrating the insulating film to be connected to the impurity region, wherein the contact electrode is made of polysilicon containing boron, and has a lower electrode part buried in the insulating film and an upper electrode part protruding from a top surface of the insulating film, the polysilicon constituting the contact electrode has a maximum grain size of 2 nm or more and 30 nm or less, and silicide is formed in at least a surface portion of the upper electrode part.

This configuration can provide the contact electrode with a high rate of charge transfer and a low resistance. Since metal contained in the silicide does not easily contaminate the impurity region through the contact electrode, properties of the solid-state image sensing device are not easily deteriorated.

A method for producing the solid-state image sensing device according to the embodiment of the present disclosure includes: forming an impurity region in a substrate; forming an insulating film on the substrate to cover the impurity region; forming a contact hole in the insulating film to expose the impurity region; depositing amorphous silicon containing boron on the insulating film to fill the contact hole; thermally treating the amorphous silicon in an inert gas atmosphere to form boron-containing polysilicon having a maximum grain size of 2 nm or more and 30 nm or less; patterning the boron-containing polysilicon to form a contact electrode having a lower electrode part buried in the contact hole and an upper electrode part protruding from a top surface of the insulating film; and forming silicide in at least a surface portion of the upper electrode part.

According to this method, a low resistance contact electrode which is in contact with the impurity region, and has the electrode upper part including a silicided surface portion can be provided, and the impurity region can be protected from metallic contamination.

In the solid-state image sensing device according to the embodiment of the present disclosure and the method for producing the same, the low resistance contact electrode connected to the impurity region of the pixel region can be provided without the metallic contamination of the impurity region. This can increase the rate of transfer of pixel signals, and can reduce noise in output images.

### BRIEF DESCRIPTION OF THE DRAWINGS

FIG. 1 is a plan view schematically illustrating a solid-state image sensing device of an embodiment of the present disclosure.

FIG. 2 is a cross-sectional view of the solid-state image sensing device taken along the line II-II in FIG. 1.

FIG. 3 is an enlarged cross-sectional view illustrating a charge storage part and its vicinity in the solid-state image sensing device of the embodiment of the present disclosure.

FIGS. 4A-4F are cross-sectional views illustrating a method for producing the solid-state image sensing device of the embodiment of the present disclosure.

FIG. 5 is a graph illustrating a relationship between a deposition rate and a deposition temperature of boron-containing amorphous silicon.

FIG. 6A is a schematic view illustrating an example of an apparatus for depositing the boron-containing amorphous silicon, and FIG. 6B is a view illustrating nozzles of the apparatus.

FIG. 7 is a graph illustrating a relationship between a position of a substrate placed in the deposition apparatus of FIG. 6A and a thickness of a deposited polysilicon film.

FIG. 8 is a graph illustrating a relationship between a temperature of a thermal treatment performed on the boron-containing amorphous silicon and a resistivity of a boron-containing polysilicon obtained after the thermal treatment.

FIG. 9A is a graph schematically illustrating a relationship between a grain size and a resistance of polysilicon. FIG. 9B is a graph schematically illustrating a relationship between a dopant concentration in polysilicon and a resistivity of polysilicon.

FIG. 9C is a graph schematically illustrating a relationship between a boron concentration in polysilicon and a resistivity of polysilicon. FIG. 9D is a graph illustrating a relationship between measurements of the boron concentration and the resistance of polysilicon obtained after the thermal treatments at different temperatures.

FIG. 10A illustrates an example of a batch-type thermal treatment apparatus, and FIG. 10B shows an example of a heating profile in the thermal treatment for forming the boron-containing polysilicon.

FIGS. 11A and 11B schematically illustrate a relationship between a rate of temperature rise in the thermal treatment and crystallization of silicon.

FIG. 12A shows the results of a back side SIMS analysis performed on a device in which a 80 nm thick polysilicon layer having a maximum grain size of about 100 nm is formed and a surface portion of the polysilicon layer is silicided, and FIG. 12B shows the results of a back side SIMS analysis performed on a device in which a 80 nm thick polysilicon layer having a maximum grain size of about 10 nm is formed and silicided.

### DETAILED DESCRIPTION

A solid-state image sensing device according to an embodiment of the present disclosure will be described in detail with reference to the drawings.

### —Overview of Solid-State Image Sensing Device—

The solid-state image sensing device according to the embodiment of the present disclosure is a device for producing images by photoelectric conversion of incident light, and is applied to various types of image sensing devices such as digital still cameras, video cameras, cellular phones, etc., and electronic equipment including these devices.

Further, a contact electrode described in detail later can reduce crystal defects at an interface between the contact electrode and an impurity region (a diffusion region), and can reduce an increase in electrical resistance between a photoelectric conversion layer and the impurity region. The photoelectric conversion layer may be made of an organic semiconductor material.

The solid-state image sensing device according to the embodiment can be produced by combining a known process for fabricating semiconductor integrated circuits and a known process for fabricating an organic solid-state image sensing device as required. The solid-state image sensing device can basically be produced by repetitively performing processes such as patterning by photolithography and etching, formation of a diffusion region by ion implantation and a thermal treatment, placement of device materials by sputtering, chemical vapor deposition (CVD), etc., removal of the materials remaining after the patterning, thermal treatments, etc. Production of an organic solid-state image sensing device additionally includes processes for forming an organic photoelectric conversion layer and a transparent electrode.

The solid-state image sensing device includes a photoelectric conversion part, a charge transfer part, a read part, electrodes, interconnections, a charge storage part, etc. in or above a substrate.

The charge transfer part and the read part are made of semiconductor materials in which mobility of charges is high. Among the semiconductor materials, silicon is preferably used to form the charge transfer part and the read part because silicon is low in cost, and can be designed under established finer design rules. Various modes for charge transfer and reading are available, and a CMOS or CCD (charge coupled device) mode is preferable among them. In particular, the CMOS mode is more preferable because the reading can be done at a higher speed, addition of pixel signals can be performed, partial reading can be performed, and power consumption can be reduced.

In the organic solid-state image sensing device, three photoelectric conversion layers which are different in adsorption wavelengths are stacked above the substrate, and each of the photoelectric conversion layers and the corresponding charge storage part are connected through electric wiring. In this case, a MIS transistor may be formed on a semiconductor substrate per image sensing pixel unit, or a CCD may be provided.

For example, in the organic solid-state image sensing device, a pixel electrode closer to the semiconductor substrate among electrodes in contact with the photoelectric conversion layer and interconnections connected to the pixel electrode may be made of any metal, and may preferably be made of copper (Cu), aluminum (Al), silver (Ag), gold (Au), chromium (Cr), tungsten (W), or an alloy of them. Among the electrodes in contact with the photoelectric conversion layer, a counter electrode facing the pixel electrode on the opposite side of the photoelectric conversion layer may be made of any metal, and may preferably be made of indium tin oxide (ITO) or indium zinc oxide (IZO) which shows particularly high transmittance to light.

In addition, color filters for dividing the incident light into red (R), green (G), and blue (B) lights, and microlenses for collecting the incident light can be provided.

The solid-state image sensing device of the embodiment of the present disclosure will be described in detail with reference to the drawings. The embodiment will be described as an example for illustrating the present disclosure and advantages thereof for convenience's sake, and does not limit the present disclosure except for essential features of the disclosure.

### —Schematic Structure of Solid-State Image Sensing Device—

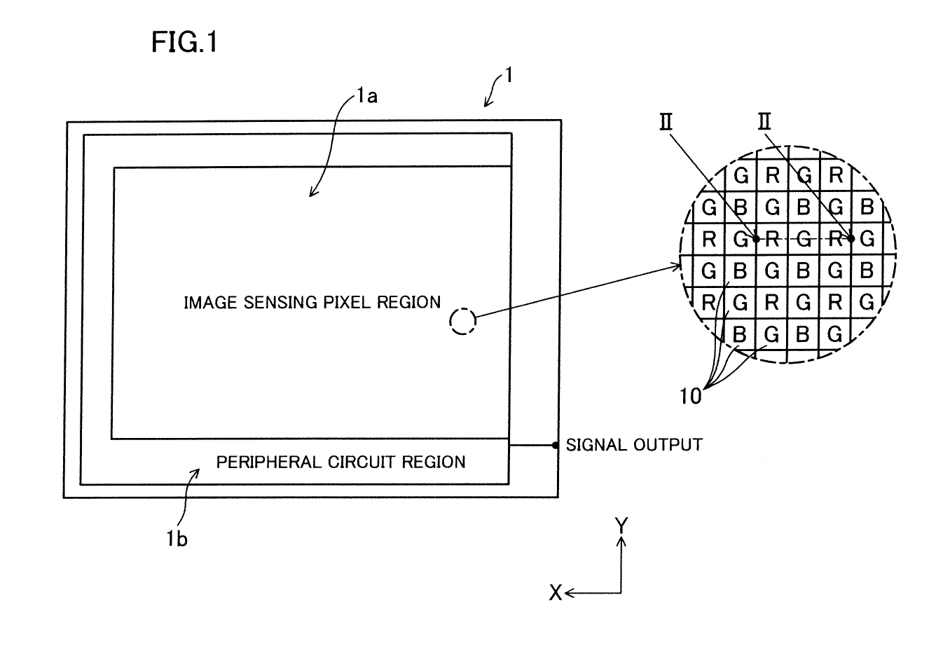

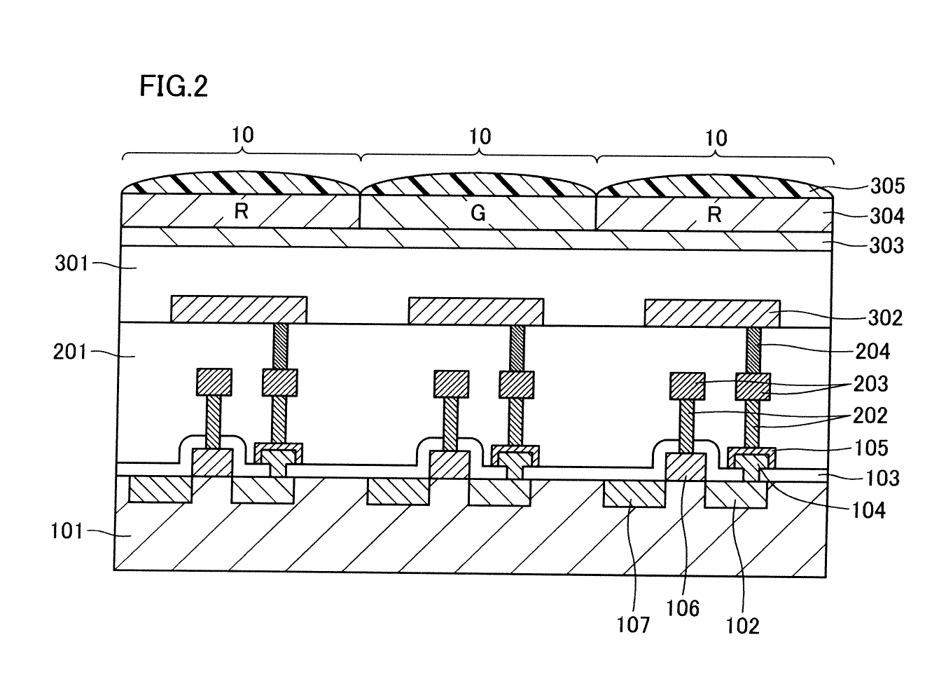

FIG. 1 is a plan view schematically illustrating the solid-state image sensing device of the embodiment of the present disclosure. FIG. 2 is a cross-sectional view of the solid-state image sensing device taken along the line II-II in FIG. 1.

As shown in FIG. 1, a solid-state image sensing device 1 of the embodiment includes an image sensing pixel region 1a in which a plurality of image sensing pixels are arranged in a two-dimensional array, and a peripheral circuit region 1b in which a logic circuit for processing signals read from the image sensing pixels is formed. The signals are read from the image sensing pixel region 1a to the peripheral circuit region 1b, and are output to the outside of the device. As enlarged in a circle on the right side of FIG. 1, the image sensing pixel region 1a of the solid-state image sensing device 1 includes a plurality of image sensing pixels 10 corresponding to different colors arranged in a two-dimensional array. Each of the image sensing pixels 10 is provided with a corresponding color filter.

As shown in FIG. 2, the solid-state image sensing device 1 of the embodiment includes a substrate 101, an interlayer insulating layer 201 formed on the substrate 101, a photoelectric conversion layer 301 formed on the interlayer insulating layer 201, pixel electrodes 302 and a counter electrode 303 formed on and below the photoelectric conversion layer 301 to face each other, color filters 304 formed on the counter electrode 303, and microlenses 305 formed on the color filters 304.

A set of the pixel electrode 302, the color filter 304, and the microlens 305 is provided for each of the image sensing pixels 10. For example, the color filters 304 may be arranged in a Bayer pattern as shown in the circle on the right side of FIG. 1.

The solid-state image sensing device 1 of the embodiment further includes a read part 107 and a charge storage part 102 formed in an upper portion of the substrate 101, a gate electrode 106 formed on the substrate 101 through a gate insulating film (not shown) to be located between the read part 107 and the charge storage part 102, an insulating film 103 covering the read part 107 and the charge storage part 102 formed in the upper portion of the substrate 101 and the gate electrode 106, a contact electrode 104, a part of which penetrating the insulating film 103 to be connected to the charge storage part 102, a metal contact 202 formed in the interlayer insulating layer 201 to be connected to the contact electrode 104 or the gate electrode 106, an interconnection connected to the metal contact 202, and an upper contact 204 formed in the interlayer insulating layer 201 to connect the interconnection 203 and the corresponding pixel electrode 302.

The contact electrode 104 is made of polysilicon containing boron (boron-doped polysilicon), and includes a lower part buried in a contact hole formed in the insulating film 103 (a lower electrode part described later), and an upper part protruding from the insulating film 103 (an upper electrode part described later). The upper electrode part includes silicide 105 formed in a surface portion thereof, i.e., in a top surface and side surfaces thereof. The silicide is not formed in the lower electrode part and between the lower electrode part and the charge storage part 102. The metal contact 202 provided on the contact electrode 104 reduces a resistance between the interconnection 203 and the contact electrode 104, and the silicide 105 reduces a contact resistance between the contact electrode 104 and the metal contact 202.

The silicide 105 may preferably be made of cobalt (Co), nickel (Ni), titanium (Ti), platinum (Pt), etc. The contact electrode 104 shown in FIG. 2 includes the silicide 105 as a part thereof. The same is applied to the following description.

The insulating film 103 is made of an insulator such as a silicon oxide film, a silicon nitride film, etc., or a stack of these insulating films. A contact hole is formed in the insulating film 103 so that the contact electrode 104 is formed therein to reach the charge storage part 102. The insulating film 103 is formed on side surfaces and a top surface of the gate electrode 106 except for part of the top surface of the gate electrode 106 to which the metal contact 202 is connected, and a top surface of the substrate 101.

The substrate 101 may preferably be a semiconductor substrate, etc., e.g., an N-type polycrystalline silicon substrate. The read part 107 and the charge storage part 102 are P-type impurity regions formed in the substrate 101, for example, and are spaced from each other in a direction of X shown in FIG. 1.

In the example shown in FIG. 2, the read part 107, the charge storage part 102, and the gate electrode 106 constitute a MIS transistor which is controlled by application of a voltage to the gate electrode 106. The MIS transistor may be provided for each of the image sensing pixels 10. Although not shown, sidewall spacers made of an insulating material are formed on the side surfaces of the gate electrode 106. The sidewall spacers may be made of a silicon oxide film, a silicon nitride film, or a stack of the silicon oxide film and the silicon nitride film. The gate electrode 106 may be made of a conductive material, preferably polysilicon containing impurities.

The read part 107 and the charge storage part 102 may be diffusion regions formed by ion implantation and thermal diffusion, or may be regions formed by CVD, etc.

Although not shown, impurity regions (or diffusion regions) containing conductive impurities, such as source/drain regions of a transistor except for the MIS transistor, are formed in a surface portion of the substrate 101. The metal contact 202, a part of which is buried in the contact hole formed in the insulating film 103, or a contact electrode made of boron-containing polysilicon is in contact with the impurity region.

Each of the color filters 304 formed on the counter electrode 303 is a filter which transmits light of a wavelength corresponding to the image sensing pixel 10. A microlens 305 made of a transparent resin, etc. is formed on each of the color filters 304. In FIG. 1 and FIG. 2, red (R), green (G), and blue (B) color filters 304 based on an additive process are shown, but cyan (C), magenta (M), and yellow (Y) color filters based on a subtractive process may also be used.

The photoelectric conversion layer 301 formed on the pixel electrodes 302 may be a mixture layer formed by simultaneous vapor deposition (flash deposition, etc.) of copper phthalocyanine and fullerene having a broad adsorption band in a visible region in the same chamber. The photoelectric conversion layer 301 absorbs light transmitted through the R, G, and B color filters 304, and generates a charge corresponding to each of the image sensing pixels 10 by photoelectric conversion.

The counter electrode 303 on the photoelectric conversion layer 301 is formed by vacuum vapor deposition. Incident light enters the photoelectric conversion layer 301 through the counter electrode 303. Thus, the counter electrode 303 is preferably made of ITO, etc. having high transmittance to light.

The charge storage part 102 stores the signal charge generated by the photoelectric conversion layer 301, and the read part 107 reads the charge read from the charge storage part 102 by application of a voltage to the gate electrode 106. To take the signal charge from the charge storage part 102, a predetermined voltage is applied to the gate electrode 106 to turn the MIS transistor on, and the signal is transmitted to the read part 107 and a signal line connected to the read part 107.

Although not shown in FIG. 2, a P-type or N-type region such as a well region is formed in addition to the charge storage part 102, and a transistor, a contact, interconnections, etc. serving as a circuit for outputting the read signal charge (signal voltage) are formed.

Signal transfer from the charge storage part 102 may be performed by using the transistor as described above, or may be performed by using a CCD.

The interconnection 203, the metal contact 202, the upper contact 204, and the contact electrode 104 function as a path for transferring the signal charge from the pixel electrode 302 to the charge storage part 102, or for transmitting a signal voltage. The metal contact 202 connected to the charge storage part 102 through the contact electrode 104 and the metal contact 202 connected to the gate electrode 106 may preferably be made of tungsten. The upper contact 204 connected to the pixel electrode 302 may preferably be made of aluminum.

The interconnection 203 may be made of a single layer, or may be made of two or more layers. The number of layers constituting the interconnection may optionally be determined depending on the type or a circuit configuration of the solid-state image sensing device.

The pixel electrode 302 may preferably be made of aluminum. In this case, an aluminum film is deposited on the interlayer insulating layer 201 by sputtering, and a resist is formed to provide a desired two-dimensional pattern on the aluminum film. Then, the pixel electrode 302 of a predetermined two-dimensional shape, e.g., a quadrangular shape, is formed by dry etching. This may be performed by a known CMOS process.

In the example shown in FIG. 2, the color filters 304 of different colors are provided, and the photoelectric conversion layer 301 is provided for the image sensing pixels 10. Instead of providing the color filters, a photoelectric conversion layer which selectively absorbs lights of R, G, and B colors may be stacked on the interlayer insulating layer 201.

### —Details of Contact Electrode in Solid-State Image Sensing Device—

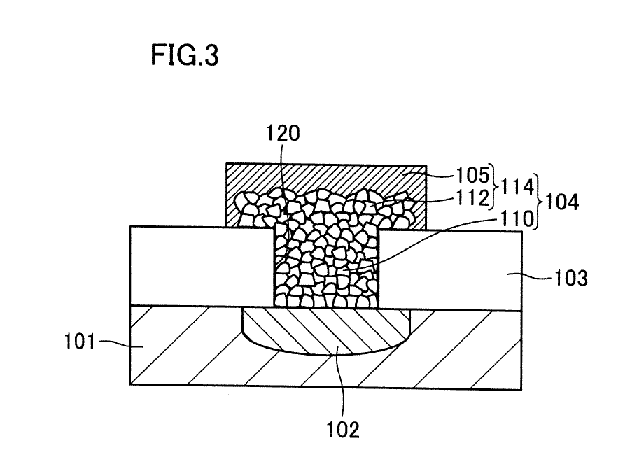

FIG. 3 is an enlarged cross-sectional view illustrating the charge storage part and its vicinity in the solid-state image sensing device according to the embodiment of the present disclosure.

As shown in FIG. 3, the contact electrode 104 is directly connected to the impurity region such as the diffusion region formed in an upper portion of the substrate 101. In FIG. 3, the charge storage part 102 is shown as an example of the diffusion region. The diffusion region designates a region in which impurities are introduced in the substrate by ion implantation and diffused by a thermal treatment, and includes the charge storage part for storing the signal charge, the read part for reading the signal charge, source/drain regions of the transistor, etc. In FIG. 3, the charge storage part 102 is illustrated to have a shape different from the charge storage part 102 shown in FIG. 2. However, as shown in FIG. 2, the charge storage part 102 may be extended toward the gate electrode 106.

Group III (Group 13) impurities such as boron, indium, etc. are diffused in the read part 107 and the charge storage part 102 so that the read part 107 and the charge storage part 102 have the P-type conductivity as the contact electrode 104 has. A two-dimensional shape of the charge storage part 102 is not particularly limited, and the charge storage part 102 may be quadrangular, for example. A planar shape of the contact electrode 104 is not particularly limited, and the contact electrode 104 may be quadrangular, circular, etc.

As shown in FIG. 3, the contact electrode 104 includes a lower electrode part 110 which is buried in a contact hole 120 formed in the insulating film 103, is made of polysilicon containing boron, and is connected to the charge storage part 102, and an upper electrode part 114 protruding from a top surface of the insulating film 103. The lower electrode part 110 and the upper electrode part 114 are independently described for convenience's sake, but they are actually integrated, i.e., the lower electrode part 110 and the upper electrode part 114 are not divided from each other.

A peripheral portion of the upper electrode part 114 is located on the insulating film 103. In other words, the upper electrode part 114 covers an edge of the contact hole formed in the insulating film 103, and an end of the upper electrode part 114 is located on the insulating film 103. Thus, the contact electrode 104 has a substantially T-shaped cross-section as shown in FIG. 2. Since the upper electrode part 114 is in such a shape, the silicide 105 can surely be formed only in the upper electrode part 114 protruding from the insulating film 103. Further, the upper electrode part 114 has a larger area than the lower electrode part 110, and the metal contact 202 directly connected to the contact electrode can be formed with a large alignment tolerance.

The upper electrode part 114 includes a portion 112 made of boron-containing polysilicon, and the silicide 105 formed in at least a surface portion of the upper electrode part 114. The silicide 105 formed only in the surface portion of the upper electrode part 114 is preferable in view of prevention of metallic contamination of the charge storage part 102, but the silicide 105 may be formed in an almost entire portion of the upper electrode part 114. The silicide 105 is preferably made of nickel silicide containing about 1-10% of platinum, but may be made of cobalt silicide, or titanium silicide.

A maximum grain size of polysilicon constituting the contact electrode 104 is preferably 2 nm or more and 30 nm or less. The maximum grain size of polysilicon is more preferably 5 nm or more and 20 nm or less. The grain size of polysilicon can be measured by a transmission electron microscope (TEM), or an X-ray diffraction analysis (XRD). The maximum grain size of polysilicon designates a maximum diameter of silicon crystal grains.

When the maximum grain size of polysilicon is in the above-described range, the surface portion of the upper electrode part 114 is surely silicided, and the silicide is prevented from reaching the surface of the charge storage part 102. This can effectively reduce the metallic contamination of the charge storage part 102.

The maximum grain size of polysilicon constituting the contact electrode 104 may be about 1/50 or more and ⅕ or less of a height of the contact electrode 104. The height of the contact electrode 104 designates a distance from an interface between the contact electrode 104 and the charge storage part 102 to a top surface of the contact electrode 104 including the silicided portion.

A boron concentration in polysilicon constituting the contact electrode 104 is about 3 atomic % or more and 5 atomic % or less. Alternatively, the boron concentration in polysilicon constituting the contact electrode 104 may be about 1.5×10²¹ atoms/cm³ or more and 2.5×10²¹ atoms/cm³ or less. For measuring the boron concentration, an X-ray fluorescence analysis (XRF) and a nuclear reaction analysis (NRA) are preferable, but secondary ion-mass spectrography (SIMS) and Rutherford backscattering spectrometry (RBS) are not preferable. This is because the high boron concentration in the contact electrode 104 cannot precisely be measured by SIMS, and boron is a light element which cannot easily be measured by RBS.

When the boron concentration in the contact electrode 104 is in the above-described range, the grain size of polysilicon in the contact electrode 104 can be controlled in the suitable range in forming the contact electrode 104. Further, the contamination of the charge storage part 102 by the silicide can be reduced, and the electrical resistance of the contact electrode 104 can sufficiently be reduced.

### —Method for Producing Solid-State Image Sensing Device—

A method for producing the solid-state image sensing device of the present embodiment will be described below based on the above-described method for producing the contact electrode 104.

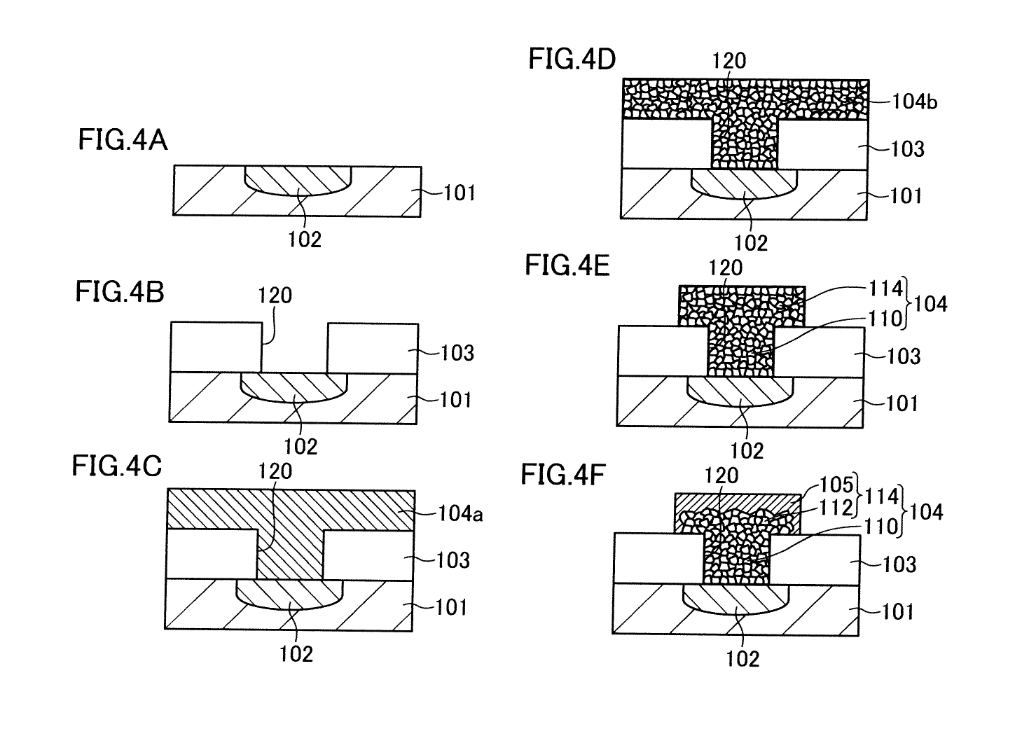

FIGS. 4A-4F are cross-sectional views illustrating steps of the method for producing a solid-state image sensing device of an embodiment of the present disclosure.

In a step shown in FIG. 4A, a resist is formed on a top surface of a substrate 101 made of an N-type semiconductor or provided with an N-type diffusion region, and the resist is patterned by lithography to form a resist mask having a predetermined pattern. Group III (Group 13) impurities such as boron, indium, etc. are implanted in a predetermined region of the substrate 101 to form an impurity diffusion layer. Then, the resist is removed, and the impurity diffusion layer is activated by a thermal treatment to form a charge storage part 102.

Processes similar to the process for forming the charge storage part 102 is repeated by changing the type of impurities to be implanted, implantation energy, conditions for the thermal treatment to form a read part, source/drain regions of the transistor, etc. in the image sensing pixel region 1a shown in FIG. 1, and to form desired diffusion regions suitable for the device such as source/drain regions in the peripheral circuit region 1b shown in FIG. 1.

Although not shown, an isolation layer called a shallow trench isolation (STI) made of silicon oxide may be formed in an upper portion of the substrate 101. The isolation layer may be formed by implanting Group V (Group 15) impurities in the substrate 101. A gate insulating film and a gate electrode are formed on the substrate 101 by a known process.

In a step shown in FIG. 4B, an insulating film 103 made of silicon oxide is formed in a thickness of about 50 nm on the substrate 101 provided with the desired diffusion region, the gate electrode, etc. Then, a resist pattern (not shown) is formed by lithography. Using the resist pattern as a resist mask, a contact hole 120 having a diameter of about 30 nm or more and 300 nm or less is formed by dry etching to expose the charge storage part 102.

When the diameter of the contact hole 120 is smaller than about 50 nm, an interface resistance between a contact electrode formed later and the charge storage part 102 tends to increase. When the diameter of the contact hole 120 is larger than about 100 nm, the charge storage part 102 is damaged by plasma in dry etching the insulating film 103, and crystal defects may occur in the charge storage part 102. Thus, the diameter of the contact hole 120 formed in the insulating film 103 is preferably about 50 nm or more and 100 nm or less.

In a step shown in FIG. 4C, boron-containing amorphous silicon 104a is deposited by CVD, etc. to fill the contact hole 120. In this step, the amorphous silicon 104a is deposited to a desired thickness in a range from about 50 nm or more to 100 nm or less on the insulating film 103.

In view of properties of the solid-state image sensing device, polymer residues and spontaneous oxide films formed on the charge storage part 102 exposed in the contact hole 120 are preferably removed using hydrofluoric acid, and a chemical oxide film is preferably formed on the charge storage part 102 using ammonia and hydrogen peroxide water before depositing the boron-containing amorphous silicon 104a.

In this step, a silicon source gas for depositing the amorphous silicon 104a is preferably silane (SiH₄). Disilane (Si₂H₆), trisilane (Si₃H₈), dichlorosilane (SiH₂Cl₂), etc. may also be used. A boron source gas is preferably boron trichloride (BCl₃). When silane and boron trichloride are reacted, hydrogen chloride (HCl) is generated to accelerate the growth of the boron-containing amorphous silicon 104a.

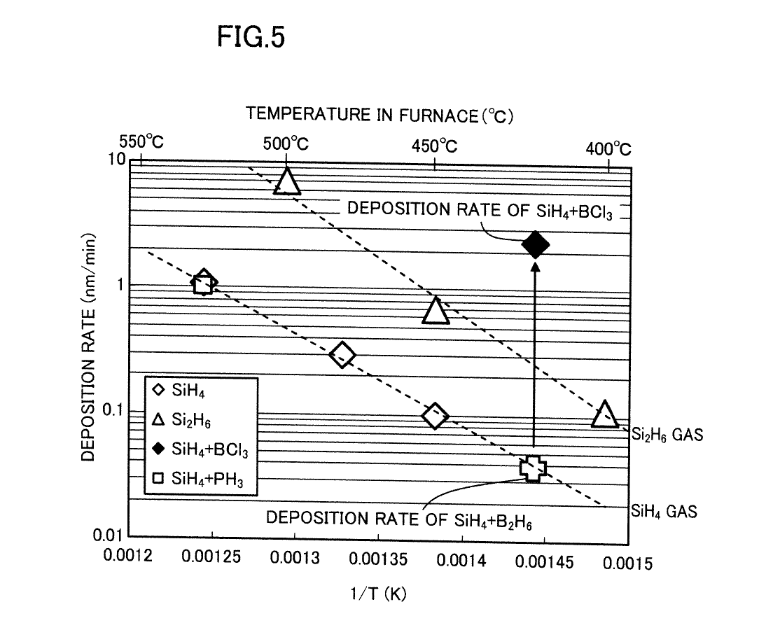

FIG. 5 is a graph illustrating a relationship between a deposition rate and a deposition temperature of the boron-containing amorphous silicon. As shown in FIG. 5, when diborane (B₂H₆) is used as the boron source gas, the growth reaction is not easily accelerated because diborane and silane are both hydrides. In this case, as indicated by symbol + in FIG. 5, the deposition rate is about 0.1 nm/min or lower (at a deposition temperature of 420° C.). When silane and boron trichloride are used, the deposition rate increases to about 2.4 nm/min at the deposition temperature of 420° C. as indicated by symbol ♦ in FIG. 5. Thus, in this embodiment, silane and boron trichloride are used as the source gases to deposit the boron-containing amorphous silicon.

In this case, depositing the amorphous silicon to a target deposition thickness of 50 nm-100 nm takes a long time. Thus, in view of throughput, a deposition apparatus for performing the deposition in a batch manner is more preferable than a deposition apparatus for performing the deposition in a one-by-one manner.

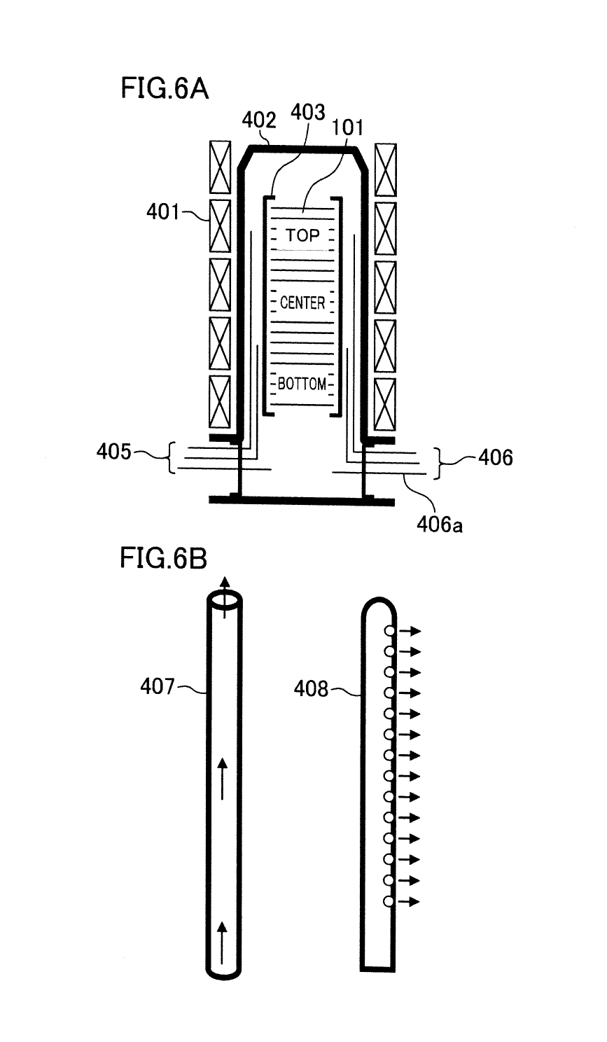

FIG. 6A schematically shows an example of an apparatus for depositing the boron-containing amorphous silicon. FIG. 6B shows nozzles of the deposition apparatus. The deposition apparatus shown in FIG. 6A is a batch-type deposition apparatus, and includes a reaction furnace 402, and a wafer boat 403 capable of carrying a plurality of the substrates 101 in the shape of wafers in the reaction furnace 402.

In depositing the amorphous silicon 104a on the substrates 101, the substrates 101 are placed on the wafer boat 403 in the reaction furnace 402 heated by a resistance heater 401, and silane is fed from a nozzle 405, and boron trichloride is fed from a nozzle 406 under reduced pressure.

Multistage nozzles (nozzles 405, 406) provided by combining nozzles 407 are used to feed boron trichloride and silane. Thus, irrespective of the position of the wafer boat 403 carrying the substrates 101, the amorphous silicon 104a of a desired thickness can be deposited on the substrates 101. Moreover, use of a multiport nozzle 408 capable of feeding boron trichloride in a direction parallel to each of the substrates 101 is effective for depositing the amorphous silicon in a uniform thickness on each substrate.

A temperature in the reaction furnace 402 is preferably about 400° C. or higher and 430° C. or lower, and a pressure in the reaction furnace 402 is preferably about 40 Pa or higher and 80 Pa or lower. More preferably, the temperature in the reaction furnace 402 is about 420° C., and the pressure is about 60 Pa.

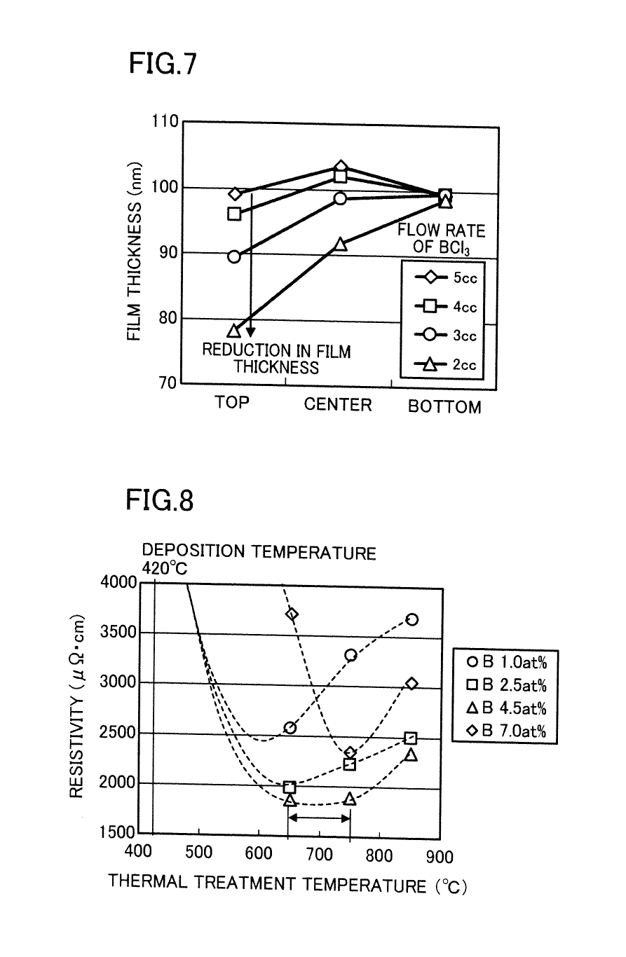

FIG. 7 is a graph illustrating a relationship between the position of the substrate in the deposition apparatus shown in FIG. 6A and the thickness of a polysilicon film deposited on the substrate. In the above-described deposition apparatus, the multistage nozzle 405 feeds silane, and only a lowest nozzle 406a in the multistage nozzle 406 feeds boron trichloride in different flow rates to compare the thicknesses of the boron-containing amorphous silicon 104a on the substrates in a top region, a center region, and a bottom region of the wafer boat 403.

As shown in FIG. 7, a reaction between silane and boron trichloride in the deposition apparatus generates hydrogen chloride, thereby accelerating the film deposition. Thus, when the flow rate of boron trichloride fed from the lowest nozzle is reduced, the amorphous silicon deposited on the substrates 101 in the top region is reduced in thickness. Thus, boron trichloride is preferably fed from the multistage nozzle (nozzle 406) or the multiport nozzle 408 shown in FIGS. 6A and 6B.

A boron concentration in the boron-containing amorphous silicon 104a is controlled such that the boron concentration is about 3 atomic % or more and 5 atomic % or less when the amorphous silicon 104a is transformed to polysilicon by a thermal treatment performed later.

The boron concentration in the amorphous silicon 104a hardly changes even after the thermal treatment, i.e., the boron concentration in the amorphous silicon remains unchanged as the boron concentration in the polysilicon. Specifically, when conditions for depositing the boron-containing amorphous silicon 104a are controlled such that the boron-containing amorphous silicon 104a has the boron concentration of about 3 atomic % or more and 5 atomic % or less, the boron concentration in the polysilicon obtained after the thermal treatment is also in the range from about 3 atomic % or more to 5 atomic % or less. For example, to control the boron concentration in the amorphous silicon 104a to 4.5 atomic %, silane is fed from the multistage nozzle 405 at 150 sccm (=mL/min), and boron trichloride is fed from the multistage nozzle 406 at 2 sccm (=mL/min).

In a step shown in FIG. 4D, the boron-containing amorphous silicon 104a is thermally treated for crystallization to form boron-containing polysilicon 104b. A maximum grain size of the boron-containing polysilicon 104b is in a range from about 2 nm or more and 30 nm or less. Further, the maximum grain size of the boron-containing polysilicon 104b is about 1/50 or more and ⅕ or less of the thickness of the boron-containing polysilicon 104b, i.e., a distance from an interface between the boron-containing polysilicon 104b and the charge storage part 102 to a top surface of the boron-containing polysilicon 104b.

FIG. 8 is a graph illustrating a relationship between the temperature of the thermal treatment performed on the boron-containing amorphous silicon 104a and a resistivity of the boron-containing polysilicon 104b obtained after the thermal treatment. FIG. 8 shows the results of a measurement on the amorphous silicon 104a deposited using the above-described deposition apparatus at 420° C.

The results shown in FIG. 8 indicate that the boron-containing polysilicon 104b shows a resistivity of 2500-3700 μΩ·cm when the boron concentration is as low as 1.0 atomic % (◯), and shows the lowest resistivity of 2500 μΩ·cm when the thermal treatment is performed at about 600° C. When the boron concentration is 2.5 atomic % (□), the boron-containing polysilicon 104b shows a resistivity of 2000-2500 μΩ·cm, and shows the lowest resistivity of 2000 μΩ·cm when the thermal treatment is performed at around 600° C. When the boron concentration is 4.5 atomic % (A), the boron-containing polysilicon 104b shows a resistivity of 1800-2400 μΩ·cm, and shows the lowest resistivity of 1800 μΩ·cm when the thermal treatment is performed at around 700±50° C.

In thermally treating polysilicon implanted with boron, the degree of activation increases and the resistance of the polysilicon decreases as the thermal treatment temperature increases. On the other hand, when the boron-containing amorphous silicon is thermally treated to obtain the boron-containing polysilicon, the resistance increases as the thermal treatment temperature increases. When the boron-containing amorphous silicon is deposited at 420° C., and the thermal treatment is performed at 600° C. or lower, the resistivity increases to approach the resistivity at 420° C.

When the boron concentration is 7.0 atomic % (O), the boron-containing polysilicon 104b shows a resistivity of 2400-3700 μΩ·cm, and shows the lowest resistivity when the thermal treatment is performed at around 750° C. Different from the dependencies on the thermal treatment temperature shown by the boron-containing polysilicons 104b having the boron concentration of 1.0-4.5 atomic % in FIG. 8, the boron concentration as high as 7.0 atomic % inhibits the crystal growth during the thermal treatment. Specifically, the resistivity of the boron-containing polysilicon obtained by thermally treating the boron-containing amorphous silicon is greatly influenced by the boron concentration in the amorphous silicon and the grain size of the polysilicon obtained after the thermal treatment.

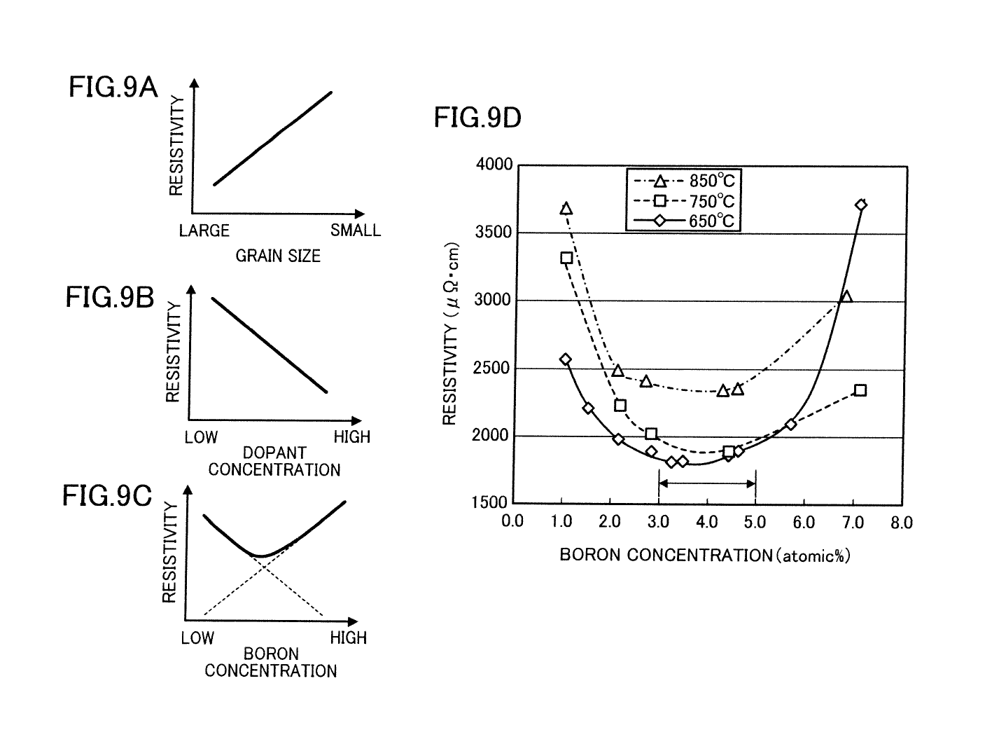

FIG. 9A is a graph schematically illustrating a relationship between the grain size and the resistivity of polysilicon. FIG. 9B is a graph schematically illustrating a relationship between a dopant concentration in polysilicon and the resistivity of polysilicon. FIG. 9C is a graph schematically illustrating a relationship between the boron concentration in polysilicon and the resistivity of polysilicon. FIG. 9D is a graph illustrating a relationship between the boron concentration in polysilicon and the resistivity of polysilicon when the thermal treatment is performed at 650° C. (O), 750° C. (O), and 850° C. (A).

In general, the resistance of polysilicon increases as the crystal grain size decreases as shown in FIG. 9A, and increases as the impurity concentration decreases as shown in FIG. 9B. However, in thermally treating the boron-containing amorphous silicon to obtain the boron-containing polysilicon, the crystallization of silicon is inhibited and the grain size of the obtained polysilicon is reduced when the boron concentration in the amorphous silicon is high. When the boron concentration is low, the crystal growth is not easily inhibited and polysilicon of a large grain size grows. Thus, as shown in FIG. 9C, when the thermal treatment is performed at a constant temperature in a range of 600° C.-900° C., the resistivity of the polysilicon does not simply increase or decrease relative to the boron concentration, but shows the lowest value relative to a certain range of the boron concentration.

The results shown in FIG. 9D indicate that the polysilicon shows approximately the lowest resistivity when the boron concentration is in a range from about 3 atomic % or more to 5 atomic % or less, irrespective of the thermal treatment temperature. A contact electrode made of the boron-containing polysilicon shows a higher resistance than a contact electrode made of a metal material, and easily causes delayed operation of the device. Thus, the resistivity of the boron-containing polysilicon is required to be as low as possible. When the boron concentration is controlled within the range from about 3 atomic % or more to 5 atomic % or less, the polysilicon contact electrode can shows approximately the lowest resistivity.

The results shown in FIG. 8 and FIG. 9D indicate that the thermal treatment temperature suitable for reducing the resistivity to a lowest level is in a range from about 650° C. or higher to 750° C. or lower. For example, the thermal treatment is performed on the boron-containing amorphous silicon in the furnace in an inert gas atmosphere such as nitrogen, etc. at a rate of temperature rise in a range from about 5° C./min or higher to 10° C./min or lower for about 5-30 minutes. The thermal treatment performed in this way can provide the boron-containing polysilicon having a resistivity of about 1800 μΩ·cm or more and 2000 μΩ·cm or less.

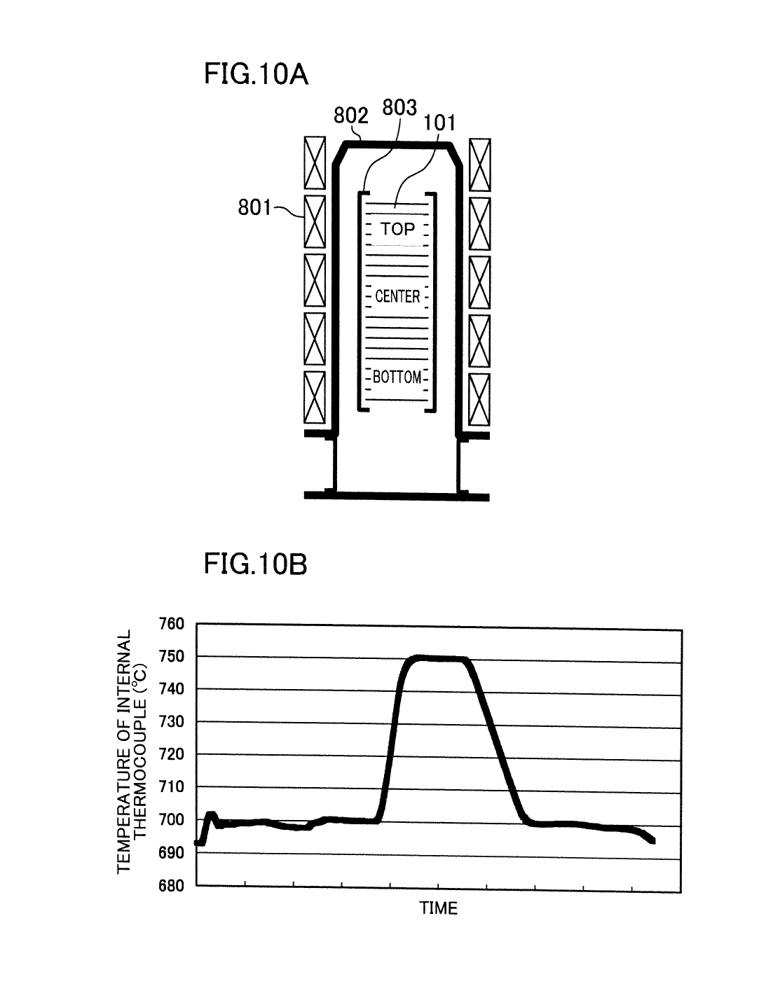

This thermal treatment can form the boron-containing polysilicon from the boron-containing amorphous silicon, and can eliminate the crystal defects in the charge storage part 102. When an apparatus for performing the thermal treatment in one-by-one manner, e.g., a lamp annealing apparatus, is used, the amorphous silicon 104a can be transformed to the polysilicon, but the crystal defects in the charge storage part 102 cannot sufficiently be eliminated. Thus, the thermal treatment is preferably performed by an apparatus for performing the thermal treatment in a batch manner as shown in FIG. 10A. The thermal treatment apparatus shown in FIG. 10A includes a heating chamber 802, a wafer boat 803 placed in the heating chamber 802 and is capable of carrying a plurality of substrates 101 in the shape of wafers, and a heater 801 for heating the heating chamber 802.

The batch-type thermal treatment apparatus is suitable for eliminating the crystal defects in the charge storage part because the apparatus can ensure a sufficient thermal treatment time without reducing productivity, and therefore, a dark current derived from the crystal defects can be reduced. The thermal treatment is performed not only in a nitrogen atmosphere, but in an inert gas atmosphere, such as argon, so that the polysilicon can be formed, and the crystal defects in the charge storage part can be eliminated.

FIG. 10B shows an example of a heating profile in the thermal treatment for forming the boron-containing polysilicon 104b. FIG. 10B shows a temperature trace log of an internal thermocouple in the center of the furnace when the thermal treatment is performed at a standby temperature of 700° C., a rate of temperature rise of 8° C./min, and a thermal treatment temperature of 750° C. for 10 minutes.

Referring to FIG. 9D, the boron-containing polysilicon obtained after a thermal treatment performed at 850° C. has a higher resistivity than the boron-containing polysilicons obtained after the thermal treatments performed at 650° C. and 750° C. The grain sizes of the boron-containing polysilicons obtained after the thermal treatments performed at different temperatures are measured by TEM. As a result, the boron-containing polysilicon obtained by the thermal treatment at 850° C. has a smaller grain size than the boron-containing polysilicon obtained by the thermal treatment at 650° C. This indicates that the thermal treatment performed at 850° C. provides the boron-containing polysilicon with the smaller grain size, thereby increasing the resistivity.

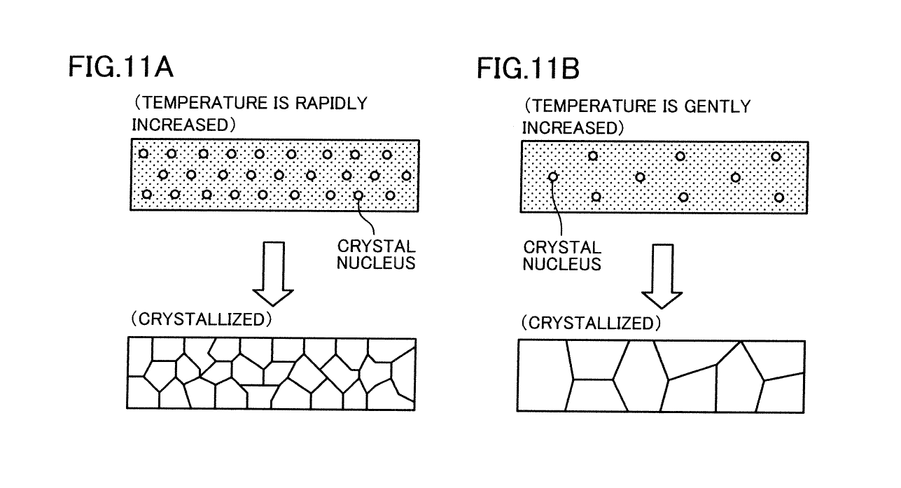

FIGS. 11A and 11B schematically show a relationship between a rate of temperature rise in the thermal treatment and crystallization of silicon. As shown in FIG. 11A, when the temperature is rapidly increased in the thermal treatment, multiple crystal nuclei are generated in the amorphous silicon, and the crystal growth proceeds based on each of the crystal nuclei. Thus, the grain size is reduced. On the other hand, as shown in FIG. 11B, when the temperature is gently increased in the thermal treatment, the growth of the crystal nuclei is reduced, and the grain size of the polysilicon is increased. When the grain size decreases, the resistivity of the polysilicon increases as shown in FIG. 9A. Thus, the gentle temperature rise is preferable to increase the grain size of the polysilicon, i.e., to provide the polysilicon.

In particular, when the maximum grain size is smaller than about 2 nm, the obtained silicon is nearly amorphous, and the resistance increases to affect the operation of the solid-state image sensing device. Thus, the temperature of the thermal treatment and the rate of temperature rise are controlled such that the maximum grain size is about 2 nm or more, preferably 5 nm or more, and that the maximum grain size is about 1/50 or more of the thickness of the boron-containing polysilicon 104b.

After the thermal treatment described above, a resist is patterned by lithography in the step shown in FIG. 4(e), and a contact electrode 104 made of the boron-containing polysilicon is formed by dry etching using the resist pattern as a mask. The contact electrode 104 includes a lower electrode part 110 buried in the contact hole 120, and an upper electrode part 114 protruding from the top surface of the insulating film 103. The upper electrode part 114 covers a top surface of part of the insulating film 103 surrounding the contact hole 120.

Although not shown, in this step, when the insulating film 103 is left around the contact hole 120 and on the gate electrode, the remaining insulating film 103 can be used as a silicide blocking layer. In other words, the insulating film 103 is left as the silicide blocking layer in the image sensing region in which the silicide is not formed in a later step on the source/drain regions and the gate electrode, while the insulating film is removed from a peripheral circuit region in which the silicide is formed on the gate electrode and the source/drain regions. Thus, the silicide can be formed only on the required region.

In the step shown in FIG. 4F, Ni, or Ni containing about 5% or more and 10% or less of Pt is deposited, and thermally treated to form Ni-containing silicide 105 in a surface portion of the upper electrode part 114 of the contact electrode 104c. Thus, the contact electrode 104 including the silicide 105 is formed. The silicide 105 can greatly reduce a contact resistance between the contact electrode 104 and the metal contact connected thereto.

After this step, an interlayer insulating layer 201, a metal contact 202, an interconnection 203, etc. are formed by a known method to produce the solid-state image sensing device of the present embodiment (see FIG. 2).

In the step of forming the silicide described above, when the maximum grain size of the boron-containing polysilicon is larger than about 30 nm, or the contact electrode 104 in which the grain size of the polysilicon is larger than about ⅕ of the thickness of the polysilicon (the height of the contact electrode 104) is formed, the grain boundary may grow from the silicide 105 to the charge storage part 102. In this case, Ni in the silicide 105 is diffused to the charge storage part 102 to generate a dark current. Thus, in the thermal treatment shown in FIG. 4D, the temperature of the thermal treatment and the rate of temperature rise are preferably controlled such that the maximum grain size of the boron-containing polysilicon 104b obtained after the thermal treatment is smaller than about 30 nm, or is about ⅕ or less of the thickness (the height) of the boron-containing polysilicon 104b. More preferably, the conditions for the thermal treatment are controlled such that the maximum grain size is about 20 nm or less.

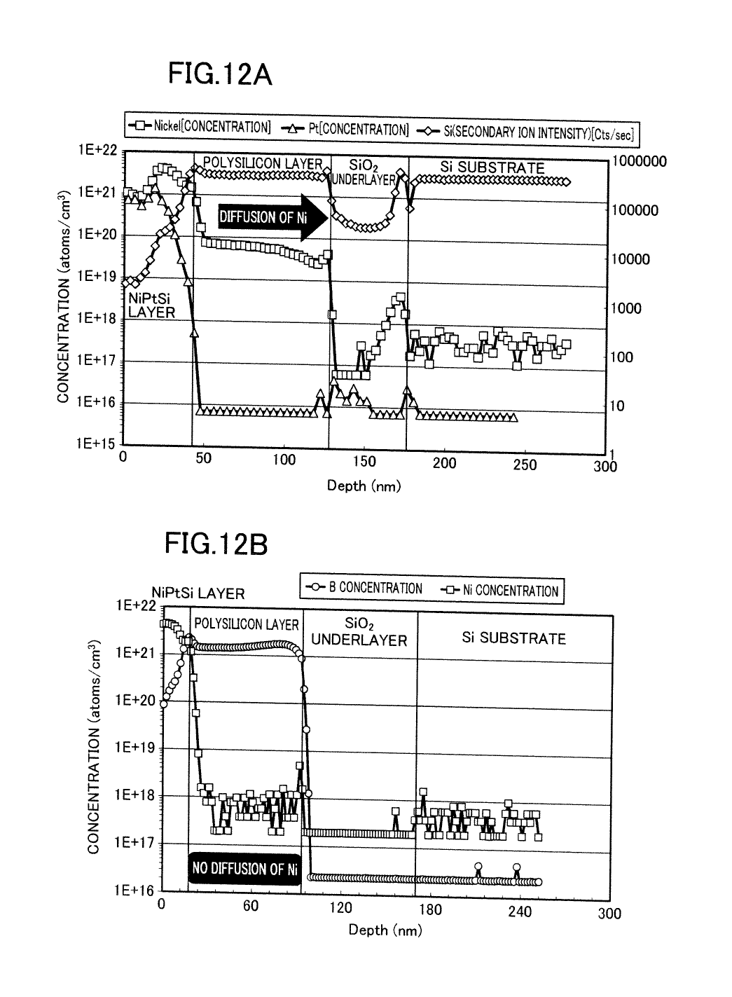

FIG. 12A shows the results of a back side SIMS analysis performed on a sample device in which an 80 nm thick polysilicon layer having a maximum grain size of about 100 nm is formed, and silicide is formed in a surface portion of the polysilicon layer. This analysis is performed on the sample device formed by sequentially stacking a SiO₂ underlayer, a polysilicon layer, a silicide layer (a NiPtSi layer) on a silicon substrate.

When Ni is not diffused, a Ni concentration in the silicon substrate is 1×10¹⁸ atoms/cm³ or less, which can be regarded as zero. However, the Ni concentration in the polysilicon layer is actually 3×10¹⁹ atoms/cm³ or more. This indicates that Ni is diffused from the polysilicon layer to the SiO₂ underlayer.

FIG. 12B shows the results of a back side SIMS analysis performed on a sample device in which an 80 nm thick polysilicon layer having a maximum grain size of about 10 nm is formed and silicided. As shown in FIG. 12B, Ni is not diffused to the bottom of the polysilicon layer, but the diffusion is stopped at the surface portion of the polysilicon layer. Thus, the diffusion of Ni is stopped at the polysilicon layer, and the Ni concentration in the polysilicon layer is about 1×10¹⁸ atoms/cm³ which is as low as the Ni concentration in the silicon substrate except for the vicinity of the silicide. This indicates that Ni is hardly diffused into the SiO₂ underlayer.

The polysilicon contact electrode leads to increase in resistivity as compared with a contact electrode made of tungsten or titanium. However, in the solid-state image sensing device of the embodiment described above, the polysilicon contact electrode is provided to solve the problems unique to the solid-state image sensing device such as the occurrence of the dark current caused by the metallic contamination. To reduce the resistance of the polysilicon contact electrode as much as possible, the grain size of polysilicon constituting the contact electrode is increased, and only the surface portion of the upper electrode part of the contact electrode is silicided.

When the grain size exceeds a certain size, or exceeds a certain range relative to the thickness of the polysilicon contact electrode, the silicide is diffused along the grain boundary to cause the metallic contamination of the charge storage part. To prevent the metallic contamination, the grain size of the polysilicon is reduced to prevent the diffusion of the silicide. Specifically, there is a trade-off between reducing the resistance of the polysilicon contact electrode 104 and preventing the diffusion of the silicide to the charge storage part 102.

In view of the above, the boron-containing polysilicon having a grain size in a desired range can be formed by depositing boron-containing amorphous silicon having a boron concentration of 3 atomic % or more and 5 atomic % or less using silane and boron trichloride, and then thermally treating the amorphous silicon at a temperature in a range from 650° C. or higher to 750° C. or lower to transform the amorphous silicon to polysilicon. As a result, the contact electrode can be provided with low resistance, and the metallic contamination of the charge storage part can sufficiently be reduced.

Since the boron concentration in the amorphous silicon is 3 atomic % or more and 5 atomic % or less, and the thermal treatment for transforming the amorphous silicon to the boron-containing polysilicon is performed at 650° C. or higher and 750° C. or lower, most of boron contained in the contact electrode 104 is captured in the silicon crystals and activated. Thus, the diffusion of boron to the charge storage part 102 can effectively be reduced. Even if a trace amount of boron is diffused to a surface portion of the charge storage part 102, the function of the charge storage part 102 is not affected.

In the present embodiment, the contact electrode 104 connected to the charge storage part 102 of the organic solid-state image sensing device has been described. The contact electrode 104 may be used as a contact electrode connected to an impurity region (a diffusion region) except for the charge storage part 102. For example, the contact electrode can be applied to a read part of an image sensing pixel region of a CMOS sensor. Moreover, the contact electrode can be used as a contact electrode connected to source/drain regions of a transistor constituting an organic solid-state image sensing device or the CMOS sensor. Particularly in the diffusion region in the image sensing pixel region in which the metallic contamination is unwanted, the low resistive contact electrode can be provided without causing the metallic contamination in the image sensing pixel region. Thus, the solid-state image sensing device can be provided with reduced noise and improved image quality.

The solid-state image sensing device and the method for producing the same have been described as an example of the present disclosure, and shapes, sizes, and materials of the parts, and production conditions can be modified within the spirit of the present disclosure.

The solid-state image sensing device of the embodiment of the present disclosure is applicable to image sensing devices such as digital still cameras, digital video cameras, etc., and various types of electronic equipment including the image sensing devices.

What is claimed is:

1. A solid-state image sensing device comprising:
a substrate provided with an impurity region;
an insulating film formed on the substrate; and
a contact electrode penetrating the insulating film to be connected to the impurity region, wherein
the contact electrode is made of polysilicon containing boron, and has a lower electrode part buried in the insulating film and an upper electrode part protruding from a top surface of the insulating film,
the polysilicon constituting the contact electrode has a maximum grain size of 2 nm or more and 30 nm or less, and
silicide is formed in at least a surface portion of the upper electrode part.

2. The solid-state image sensing device of claim 1, wherein
the impurity region is a diffusion region.

3. The solid-state image sensing device of claim 2, wherein
the diffusion region is a charge storage part.

4. The solid-state image sensing device of claim 1, wherein
a peripheral portion of the upper electrode part is located on the insulating film.

5. The solid-state image sensing device of claim 1, wherein
the polysilicon constituting the contact electrode has a maximum grain size of 1/50 or more and ⅕ or less of a height of the contact electrode.

6. The solid-state image sensing device of claim 1, further comprising:
a metal contact connected to the upper electrode part.

7. The solid-state image sensing device of claim 1, wherein
the polysilicon constituting the contact electrode has a boron concentration of 3 atomic % or more and 5 atomic % or less.

8. The solid-state image sensing device of claim 1, wherein
the polysilicon constituting the contact electrode has a boron concentration of 1.5×10²¹ atoms/cm³ or more and 2.5×10²¹ atoms/cm³ or less.

9. The solid-state image sensing device of claim 1, wherein
the silicide is nickel silicide, cobalt silicide, or titanium silicide.

10. The solid-state image sensing device of claim 1, wherein
the polysilicon constituting the contact electrode has a resistivity of 1800 μΩ·cm or more and 2000 μΩ·cm or less.

11. A method for producing a solid-state image sensing device, the method comprising:
forming an impurity region in a substrate;
forming an insulating film on the substrate to cover the impurity region;
forming a contact hole in the insulating film to expose the impurity region;
depositing amorphous silicon containing boron on the insulating film to fill the contact hole;
thermally treating the amorphous silicon in an inert gas atmosphere to form boron-containing polysilicon having a maximum grain size of 2 nm or more and 30 nm or less;
patterning the boron-containing polysilicon to form a contact electrode having a lower electrode part buried in the contact hole and an upper electrode part protruding from a top surface of the insulating film; and
forming silicide in at least a surface portion of the upper electrode part.

12. The method for producing the solid-state image sensing device of claim 11, wherein
a temperature for thermally treating the amorphous silicon to form the boron-containing polysilicon is 650° C. or higher and 750° C. or lower.

13. The method for producing the solid-state image sensing device of claim 11, wherein
a batch-type thermal treatment apparatus is used for thermally treating the amorphous silicon to form the boron-containing polysilicon.

14. The method for producing the solid-state image sensing device of claim 11, wherein
the impurity region is a charge storage part.

15. The method for producing the solid-state image sensing device of claim 11, the method further comprising:
forming a metal contact connected to the upper electrode part after the formation of the silicide.

16. The method for producing the solid-state image sensing device of claim 11, wherein
the amorphous silicon has a boron concentration of 3 atomic % or more and 5 atomic % or less.

17. The method for producing the solid-state image sensing device of claim 11, wherein
the amorphous silicon has a boron concentration of 1.5×10²¹ atoms/cm³ or more and 2.5×10²¹ atoms/cm³ or less.
